(19) United States
(12) Patent Application Publication
(10) Pub. No.: US 2010/0194446 A1
(43) Pub. Date: Aug. 5, 2010

(54) SOURCE DRIVER, DELAY CELL IMPLEMENTED IN THE SOURCE DRIVER, AND CALIBRATION METHOD FOR CALIBRATING A DELAY TIME THEREOF

(76) Inventor: Tzong-Yau Ku, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/363,790

(22) Filed: Feb. 2, 2009

(51) Int. Cl. H03K 3/00; H03H 11/26

(52) U.S. Cl. 327/108; 327/288; 327/261

(57) ABSTRACT

A delay cell for delaying an input data signal to generate an output data signal includes a logic circuit and a bias current generator. The logic circuit is used for processing the input data signal to generate the output data signal. The bias current generator is coupled to the logic circuit for providing a first bias current to the logic circuit to control a delay time of the delay cell based on a process corner at which the delay cell is manufactured in a wafer. The bias current generator includes a first transistor coupled between a first power supply and the logic circuit for steering the first bias current of the logic circuit, wherein the first transistor is biased by a first bias voltage.

### BACKGROUND OF THE INVENTION

1. Field of the Invention

The present invention relates to a delay cell, and more particularly, to a delay cell for controlling a delay time based on a process corner.

2. Description of the Prior Art

Liquid crystal display (LCD) devices are flat panel displays characterized by their thin appearance, low radiation and low power consumption. LCD devices have gradually replaced traditional cathode ray tube (CRT) displays, and have been widely applied in various electronic products such as notebook computers, personal digital assistants (PDAs), flat panel televisions, or mobile phones. An LCD device usually includes an LCD panel, a timing controller, a gate driver, and a source driver. The timing controller is used for generating image data signals, together with control signals and timing signals for driving the LCD panel. The gate driver is used for generating scan signals for turning the pixel circuits on and off, and the source driver is used for generating driving signals based on the image data signals, the control signals and the timing signals.

In semiconductor fabrication, a process corner represents a three or six sigma variation from nominal doping concentrations in transistors on a silicon wafer. This variation may occur for many reasons, such as minor changes in the humidity or temperature changes in the clean-room between wafers, or due to the position of the die relative to the center of the wafer. Apart from the typical corner, there are fast and slow corners, where the carrier mobility is higher and lower than normal, respectively.

Process corners carry two-letter designators, where the first letter refers to the PMOS corner, and the second letter refers to the NMOS corner. For example, the FS corner designates fast PMOS transistors and slow NMOS transistors. There are therefore five possible corners: typical-typical (TT), fast-fast (FF), slow-slow (SS), fast-slow (FS), and slow-fast (SF).

FIG. 1 is a diagram showing a delay cell disposed in a source driver 100 according to the prior art. The source driver 100 includes a clock signal receiver 110 and a data signal receiver 150. The clock signal receiver 110 receives a pair of differential clock signals CLK_P and CLK_N. The data signal receiver receives a pair of differential input data signals D_{IN—}P and D_{IN—}N. In order to let the source driver 100 meet the data setup/hold time specification, a suitable delay cell 170 is inserted into the data signal path. The delay cell 170 is coupled to the data signal receiver 150 via a logic block 160 for delaying the pair of differential input data signals D_{IN—}P and D_{IN—}N to generate an output data signal D_{OUT} while a buffer 130 is coupled to the clock signal receiver 110 via a logic block 120 for generating an output clock signal CLK_{OUT}. The delay cell 170 has different delay times at different process corners (e.g. TT/FF/SS). Because the setup/hold time of the source driver 100 is affected by the delay time of the delay cell 170, the setup/hold time of the source driver 100 is different at different process corners.

A voltage range of the source driver 100, however, becomes larger at different process corners. Thus, it is hard to meet the data setup/hold time specification at this larger voltage range at all process corners. As a result, improving the data setup/hold time issue at this larger voltage range and improving the delay time difference within the same delay cell at different process corners has become an important topic in the field of LCD devices.

### SUMMARY OF THE INVENTION

It is therefore one of the objectives of the claimed invention to provide a delay cell and related source driver and method to solve the abovementioned problems.

According to one embodiment, a delay cell for delaying an input data signal to generate an output data signal is provided. The delay cell includes a logic circuit and a bias current generator. The logic circuit is used for processing the input data signal to generate the output data signal. The bias current generator is coupled to the logic circuit for providing a first bias current to the logic circuit to control a delay time of the delay cell based on a process corner at which the delay cell is manufactured in a wafer. The bias current generator includes a first transistor coupled between a first power supply and the logic circuit for steering the first bias current of the logic circuit, wherein the first transistor is biased by a first bias voltage.

According to one embodiment, a source driver is provided. The source driver includes a clock signal receiver, a data signal receiver, and a delay cell. The clock signal receiver receives a clock signal. The data signal receiver receives an input data signal. The delay cell is coupled to the data signal receiver for delaying the input data signal to generate an output data signal. The delay cell includes a logic circuit and a bias current generator. The logic circuit is used for processing the input data signal to generate the output data signal. The bias current generator is coupled to the logic circuit for providing a first bias current to the logic circuit to control a delay time of the delay cell based on a process corner at which the delay cell is manufactured in a wafer. A setup time and a hold time between the clock signal and the output data signal is controlled by the first bias current according to the process corner.

According to one embodiment, a calibration method for calibrating a delay time of a first logic circuit and a second logic circuit is provided. The first logic circuit and the second logic circuit are identical logic circuits but have manufacturing deviations between them. The calibration method includes determining a first bias current for the first logic circuit; determining a second bias current for the second logic circuit; providing the first bias current to the first logic circuit; and providing the second bias current to the second logic circuit, wherein a first time of the first logic circuit is substantially equal to a second delay time of the second logic circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a delay cell disposed in a source driver according to the prior art.

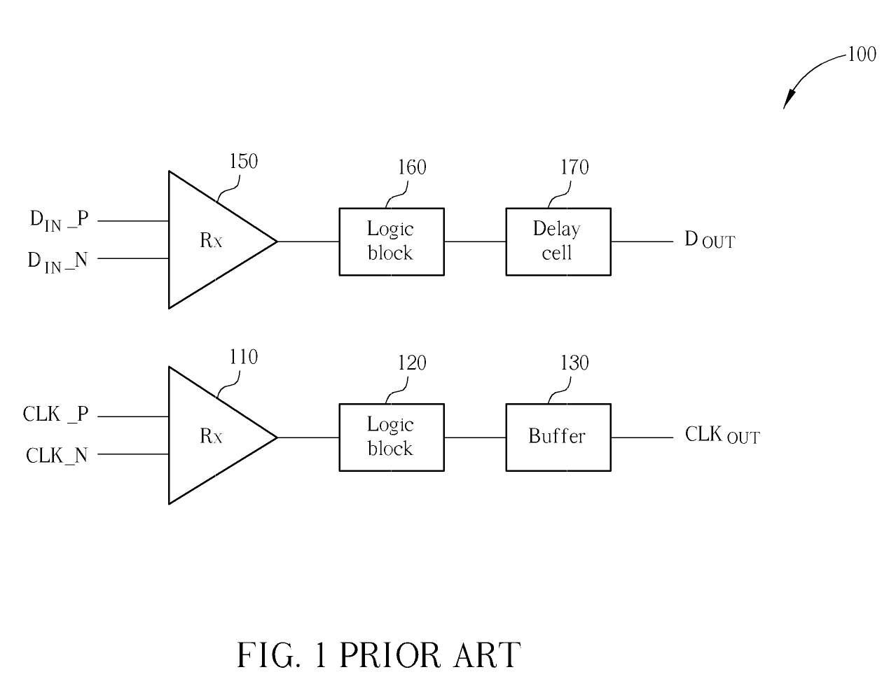

FIG. 2 is a diagram of a delay cell according to a first embodiment of the present invention.

FIG. 3 is a diagram of a delay cell according to a second embodiment of the present invention.

FIG. 4 is a diagram of a delay cell according to a third embodiment of the present invention.

FIG. 5 is a diagram of a delay cell according to a fourth embodiment of the present invention.

FIG. 6 is a diagram showing how the bias current generator shown in FIG. 2 determines the first bias voltage according to an embodiment of the present invention.

FIG. 7 is a flowchart illustrating a calibration method for calibrating a delay time of a first logic circuit and a second logic circuit according to an exemplary embodiment of the present invention.

### DETAILED DESCRIPTION

Certain terms are used throughout the following description and claims to refer to particular components. As one skilled in the art will appreciate, hardware manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . ”. The terms “couple” and “coupled” are intended to mean either an indirect or a direct electrical connection. Thus, if a first device couples to a second device, that connection may be through a direct electrical connection, or through an indirect electrical connection via other devices and connections.

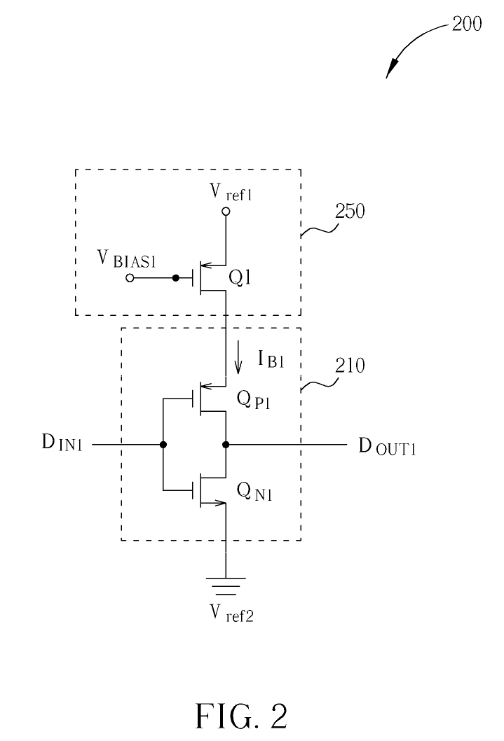

FIG. 2 is a diagram of a delay cell 200 according to a first embodiment of the present invention. The delay cell 200 is used for delaying an input data signal D_{IN1} to generate an output data signal D_{OUT1}. The delay cell 200 includes a logic circuit 210 and a bias current generator 250. The logic circuit 210 is used for processing the input data signal D_{IN1} to generate the output data signal D_{OUT1}. In this embodiment, the logic circuit 210 is an inverter and has a PMOS transistor Q_{P1} and an NMOS transistor Q_{N1} cascaded to each other. People skilled in the art will readily appreciate that other designs of implementing the logic circuit 210 are feasible. The bias current generator 250 is coupled to the logic circuit 210 for providing a first bias current I₁ to the logic circuit 210 to control a delay time of the delay cell 200 based on a process corner.

In this embodiment, the bias current generator 250 is implemented by a first transistor Q1, which is a PMOS transistor. The first transistor Q1 is coupled between a first power supply V_{ref1} and the logic circuit 210 for steering the first bias current I_{B1} of the logic circuit 210. The first transistor Q1 is biased by a first bias voltage V_{BIAS1}. Due to the first transistor Q1 being biased by the first bias voltage B_{BIAS1}, the first bias current I_{B1} flowing through the first transistor Q1 is controlled according to the first bias voltage V_{BIAS1}. Assume that before the first bias current I_{B1} is provided to the logic circuit 210, a current I_{F1} flows through the logic circuit 210 if the logic circuit 210 is at the FF corner, and a current I_{S1} flows through the logic circuit 210 if the logic circuit 210 is at the SS corner, wherein the current I_{F1} is greater than the current I_{S1}. If the first bias current I_{B1} is set to be the same as the current I_{S1} at the SS corner, the current I_{F1} at the FF corner can be restricted to be the same as the current I_{S1} (i.e., I_{F1}=I_{B1}=I_{S1}). Therefore, the delay time difference within the same delay cell 200 at different process corners can be improved.

The abovementioned embodiment is merely an example for illustrating features of the present invention and should not be seen as limitations of the present invention. Those skilled in the art should appreciate that various modifications of the first bias current I_{B1} may be made. For example, the first bias current I_{B1} can be set to be smaller than the current I_{F1} and larger than the current I_{S1} (i.e., I_{S1}<I_{B1}<I_{F1}), and this also belongs within the scope of the present invention.

Please note that the delay cell 200 can be applied to a source driver of an LCD panel, but the present invention is not limited to this arrangement. In other embodiments, the delay cell 200 can be applied to other applications.

Be compared the delay time of the conventional delay cell with the delay time of the delay cell disclosed in the present invention at different process corners, the delay time of the conventional delay cell at the SS/FF corner is smaller than the delay time of the delay cell disclosed in the present invention at the SS/FF corner. In addition, the delay time difference (i.e., the difference between the delay time at the SS corner and the FF corner) of the delay cell disclosed in the present invention is considerably smaller than the delay time difference of the conventional delay cell. Therefore, the setup/hold time may cause failure at some process corners if the conventional delay cell is adopted while the setup/hold time all pass at all the process corners if the delay cell disclosed in the present invention is adopted. In other words, the performance of the delay cell disclosed in the present invention is much better than the conventional delay cell.

Of course, the abovementioned embodiment is merely an example for illustrating features of the present invention and should not be seen as limitations of the present invention. Those skilled in the art should appreciate that various modifications of the bias current generator 250 may be made without departing from the spirit of the present invention.

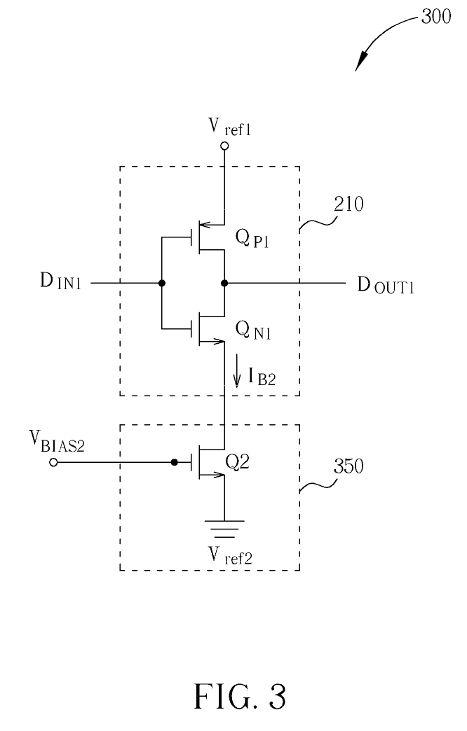

FIG. 3 is a diagram of a delay cell 300 according to a second embodiment of the present invention. The delay cell 300 shown in FIG. 3 is similar to the delay cell 200 shown in FIG. 2, the difference between them being that the bias current generator 350 of the delay cell 300 in this embodiment is implemented by a second transistor Q2, which is an NMOS transistor. The second transistor Q2 is coupled between a second power supply V_{ref2,}, such as ground, and the logic circuit 210 for steering a second bias current I_{B2} of the logic circuit 210. Please note that the second transistor Q2 is biased by a second bias voltage V_{BIAS2}. Due to the second transistor Q2 being biased by the second bias voltage B_{BIAS2}, the second bias current I_{B2} flowing through the second transistor Q2 is controlled according to the second bias voltage V_{BIAS2}. By adopting the method of work, the delay time of the delay cell at different process corners may approximate to each other.

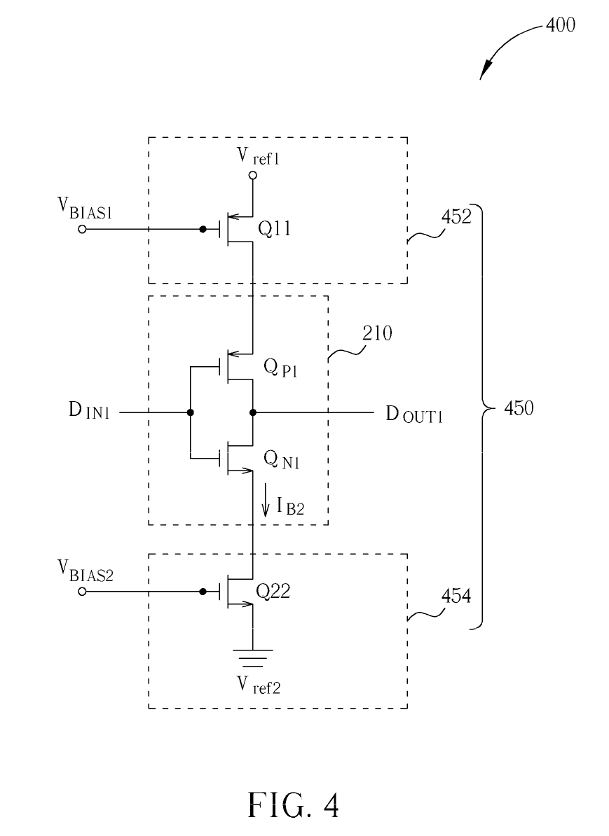

FIG. 4 is a diagram of a delay cell 400 according to a third embodiment of the present invention. The delay cell 400 shown in FIG. 4 is similar to the delay cell 200 shown in FIG. 2, the difference between them being that the bias current generator 450 of the delay cell 400 has a first block 452 implemented by a biased PMOS transistor Q11 and a second block 454 implemented by a biased NOMS transistor Q22. In other words, the third embodiment is a combination of the first embodiment and the second embodiment.

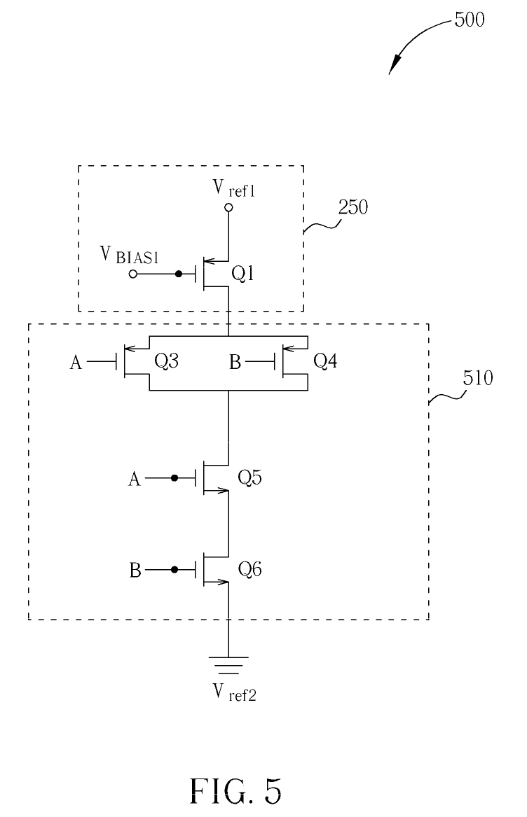

FIG. 5 is a diagram of a delay cell 500 according to a fourth embodiment of the present invention. The delay cell 500 shown in FIG. 5 is similar to the delay cell 200 shown in FIG. 2, the difference between them being that the logic circuit 510 of delay cell 500 is different from the logic circuit 210 of the delay cell 200. In this embodiment, the logic circuit 510 is a circuit for achieving a NAND gate. The connection manner of the four transistors Q3-Q6 is shown in FIG. 5, and further description is therefore omitted here for brevity. People skilled in the art will readily appreciate that other designs of implementing the logic circuit are feasible.

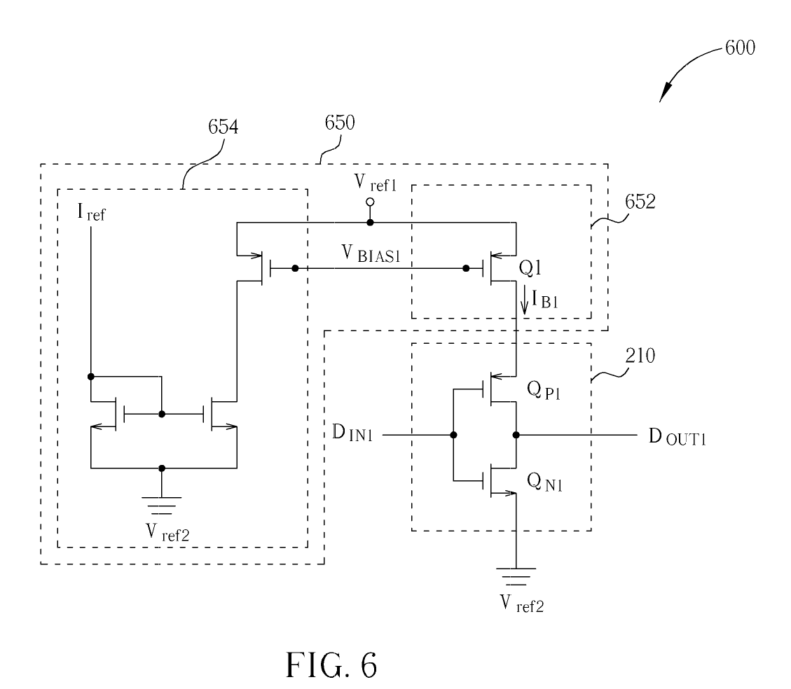

FIG. 6 is a diagram showing how the bias current generator shown in FIG. 2 determines the first bias voltage according to an embodiment of the present invention. As shown in FIG. 6, except for the first transistor Q1 (i.e., the first part 652), the bias current generator 650 of the delay cell 600 further includes a current mirror 654 coupled to the first transistor Q1 for determining the first bias voltage V_{BIAS1}. Since the detailed operations of the current mirror 654 are commonly known to those skilled in the art, further details are omitted here for the sake of brevity.

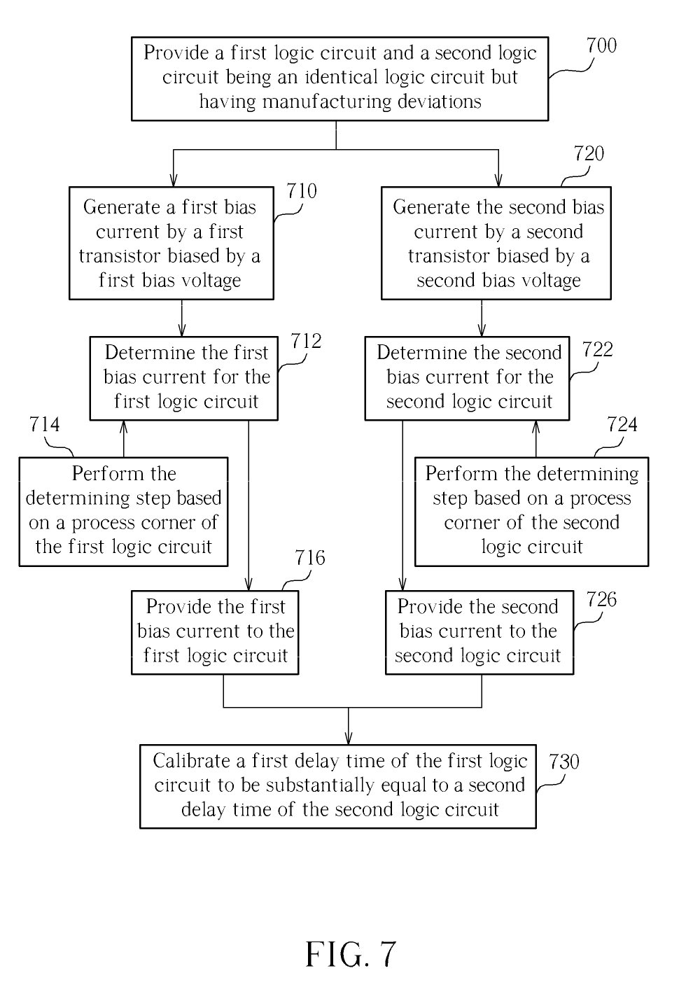

FIG. 7 is a flowchart illustrating a calibration method for calibrating a delay time of a first logic circuit and a second logic circuit according to an exemplary embodiment of the present invention. Please note that the following steps are not limited to be performed according to the exact sequence shown in FIG. 7 if a roughly identical result can be obtained. The remote live pause method includes, but is not limited to, the following steps:

Step 700: Provide a first logic circuit and a second logic circuit being an identical logic circuit but having manufacturing deviations between them.

Step 710: Generate a first bias current by a first transistor biased by a first bias voltage.

Step 712: Determine the first bias current for the first logic circuit.

Step 714: Perform the determining step based on a process corner of the first logic circuit at which the first logic circuit is manufactured in a wafer.

Step 716: Provide the first bias current to the first logic circuit.

Step 720: Generate the second bias current by a second transistor biased by a second bias voltage.

Step 722: Determine the second bias current for the second logic circuit.

Step 724: Perform the determining step based on a process corner of the second logic circuit at which the second logic circuit is manufactured in a wafer.

Step 726: Provide the second bias current to the second logic circuit.

Step 730: Calibrate a first delay time of the first logic circuit to be substantially equal to a second delay time of the second logic circuit.

Due to the first logic circuit and the second logic circuit being an identical logic circuit but having manufacturing deviations between them, the first delay time of the first logic circuit may be different from the second delay time of the second logic circuit. Through generating the first bias current by the first transistor biased by a first bias voltage, the first bias current for the first logic circuit can be determined to control the response speed of the first logic circuit (the steps 710-716). Through generating the second bias current by the second transistor biased by the second bias voltage, the second bias current for the second logic circuit can be determined to control the response speed of the second logic circuit (the steps 720-726). In addition, the determining steps 712 and 722 are respectively performed based on the process corner of the first logic circuit and the process corner of the second logic circuit (Step 714 and Step 714). Therefore, the first delay time of the first logic circuit can be calibrated to be substantially equal to the second delay time of the second logic circuit at different process corners (Step 730).

Please note that, the method shown in FIG. 7 is one practicable embodiment, rather than limiting conditions of the present invention. Furthermore, the order of the steps merely represents a preferred embodiment of the method of the present invention. In other words, the illustrated order of steps can be changed based on the conditions, and is not limited to that mentioned above.

The abovementioned embodiments are presented merely for describing features of the present invention, and in no way should be considered to be limitations of the scope of the present invention. In summary, the present invention provides a delay cell implemented in a source driver of an LCD panel and a related device and calibration method. Through adding one or two biased MOS transistors into the delay cell, the delay time (or the response speed) of the delay cell can be controlled by determining the bias current of the logic circuit inside the delay cell. Therefore, the delay time difference between different process corners (such as the FF and SS corners) of the delay cell disclosed in the present invention can be improved. In addition, the setup/hold time is also improved by adopting the conventional delay cell to let the source driver meet the setup/hold time specification. As is demonstrated by the above description, the performance of the delay cell disclosed in the present invention is much better than the conventional delay cell. No matter whether manufacturing deviations exist between the logic circuits or the voltage range of the source driver gets larger, the problems occurring in the prior art can be overcome by adopting the delay cell disclosed in the present invention. Furthermore, only one or two biased MOS transistors are added into the delay cell, which does not significantly increase the cost.

Those skilled in the art will readily observe that numerous modifications and alterations of the device and method may be made while retaining the teachings of the invention.

What is claimed is:

1. A delay cell for delaying an input data signal to generate an output data signal, the delay cell comprising:
a logic circuit, for processing the input data signal to generate the output data signal; and
a bias current generator, coupled to the logic circuit, for providing a first bias current to the logic circuit to control a delay time of the delay cell based on a process corner.

2. The delay cell of claim 1, wherein the bias current generator comprises:
a first transistor, coupled between a first power supply and the logic circuit for steering the first bias current of the logic circuit, where the first transistor is biased by a first bias voltage.

3. The delay cell of claim 2, wherein the bias current generator further comprises:
a current mirror, coupled to the first transistor, for determining the first bias voltage.

4. The delay cell of claim 2, wherein the bias current generator further comprises:
a second transistor, coupled between a second power supply and the logic circuit for steering a second bias current of the logic circuit, where the second transistor is biased by a second bias voltage.

5. The delay cell of claim 4, wherein the first transistor is a PMOS transistor and the second transistor is an NMOS transistor.

6. The delay cell of claim 1, being implemented in a source driver of an LCD panel.

7. A source driver, comprising:
a clock signal receiver, for receiving a clock signal;
a data signal receiver, for receiving an input data signal;
a delay cell, coupled to the data signal receiver, for delaying the input data signal to generate an output data signal, the delay cell comprising:
a logic circuit, for processing the input data signal to generate the output data signal; and
a bias current generator, coupled to the logic circuit, for providing a first bias current to the logic circuit to control a delay time of the delay unit based on a process corner at which the delay cell is manufactured in a wafer;
wherein a setup time and a hold time between the clock signal and the output data signal is controlled by the first bias current according to the process corner.

8. The source driver of claim 7, wherein the bias current generator comprises:
a first transistor, coupled between a first power supply and the logic circuit for steering the first bias current of the logic circuit, where the first transistor is biased by a first bias voltage.

9. The source driver of claim 8, wherein the bias current generator further comprises:
a current mirror, coupled to the first transistor, for determining the first bias voltage.

10. The source driver of claim 8, wherein the bias current generator further comprises:
a second transistor, coupled between a second power supply and the logic circuit for steering a second bias current of the logic circuit, where the second transistor is biased by a second bias voltage.

11. The source driver of claim 10, wherein the first transistor is a PMOS transistor and the second transistor is an NMOS transistor.

12. A calibration method for calibrating a delay time of a first logic circuit and a second logic circuit, the first logic circuit and the second logic circuit being identical logic circuits but having manufacturing deviations between them, the calibration method comprising:
determining a first bias current for the first logic circuit;
determining a second bias current for the second logic circuit;
providing the first bias current to the first logic circuit; and
providing the second bias current to the second logic circuit, wherein a first delay time of the first logic circuit is substantially equal to a second delay time of the second logic circuit.

13. The calibration method of claim 12, further comprising:
generating the first bias current by a first transistor biased by a first bias voltage; and
generating the second bias current by a second transistor biased by a second bias voltage.

14. The calibration method of claim 13, wherein the first logic circuit is connected to a first power supply via the first transistor, and the second logic circuit is connected to a second power supply via the second transistor.

15. The calibration method of claim 12, wherein the step of determining the first bias current is performed based on a process corner of the first logic circuit at which the first logic circuit is manufactured in a wafer.

16. The calibration method of claim 15, wherein the step of determining the second bias current is performed based on a process corner of the second logic circuit at which the second logic circuit is manufactured in the wafer.
